(19) United States
(12) Patent Application Publication
(10) Pub. No.: US 2019/0280130 A1
(43) Pub. Date: Sep. 12, 2019

(54) ENCAPSULATING COVER FOR AN ELECTRONIC PACKAGE AND FABRICATING PROCESS

(71) Applicants: STMicroelectronics (Grenoble 2) SAS, Grenoble (FR); STMicroelectronics (Research & Development) Limited, Marlow (GB)

(72) Inventors: Karine SAXOD, Les Marches (FR); Nicolas MASTROMAURO, Lumbin (FR); Colin CAMPBELL, Darvel (GB)

(73) Assignees: STMicroelectronics (Grenoble 2) SAS, Grenoble (FR); STMicroelectronics (Research & Development) Limited, Marlow (GB)

(21) Appl. No.: 16/295,045

(22) Filed: Mar. 7, 2019

(30) Foreign Application Priority Data
Mar. 8, 2018 (FR) 1852018

(51) Int. Cl. H01L 31/0203; H01L 31/12; H01L 31/0232; H01L 33/52; H01L 33/58; H01L 25/16

(52) U.S. Cl. CPC H01L 31/0203; H01L 31/12; H01L 25/167; H01L 33/52; H01L 33/58; H01L 31/0232

(57) ABSTRACT

Encapsulating cover for an electronic package is formed by a cover body having a front wall and, positioned around a through-passage, a mounting face that includes a bearing surface. A mounting face of an optical element bears against the bearing surface. The mounting face includes at least one local void that is set back with respect to the bearing surface to provide a space between the mounting face of the optical element and the bottom of the local void. The local void extends beyond an edge of the optical element. A drop of fastening adhesive extends locally into said local void and has a portion that is covered by the optical element and an uncovered portion that is located beyond the edge of the optical element.

### PRIORITY CLAIM

This application claims the priority benefit of French Application for Patent No. 1852018, filed on Mar. 8, 2018, the content of which is hereby incorporated by reference in its entirety to the maximum extent allowable by law.

### TECHNICAL FIELD

The present invention relates to the field of microelectronics and more particularly to the field of electronic packages comprising covers for encapsulating carrier-mounted electronic chips.

### SUMMARY

An encapsulating cover for an electronic package comprises a cover body having a front wall containing a through-passage and comprising an optical element that lets light pass, said optical element being placed facing the through-passage and being fastened to said front wall by at least one drop of fastening adhesive.

The front wall of the cover body has, around said through-passage, a mounting face that comprises a bearing surface against which a mounting face of the optical element bears and that comprises at least one local void that is set back with respect to said bearing surface, that creates a space between the mounting face of the optical element and the bottom of the local void, and that extends beyond an edge of the optical element.

The drop of fastening adhesive extends locally into said local void and has a portion that is covered by the optical element and an uncovered portion that is located beyond said edge of the optical element.

Said local void may be located a distance away from said through-passage.

The bearing surface may comprise a zone that extends all the way around said through-passage and that passes between said through-passage and said local void.

The bottom of the local void may contain a protruding bump that lies facing and a distance away from the mounting face of the optical element and that extends beyond said edge of the optical element, said drop of fastening adhesive extending over this protruding bump.

Said front wall may contain a housing the bottom of which comprises said mounting face, a space being provided between said edge of the optical element and a side wall of the housing, the uncovered portion of the drop of fastening adhesive being located in this space.

An electronic package is also provided, said package comprising a carrier equipped, on a mounting face, with at least one electronic chip including an optical component and an encapsulating cover such as defined above.

The front wall equipped with the optical element of the cover body lies above and a distance away from the chip.

The cover body comprises a peripheral wall that protrudes with respect to the front wall, lying around and a distance away from the chip and fastened to the mounting face of the carrier, so as to define a cavity in which the chip is located.

According to one variant embodiment, the optical element may be located in the interior of said cavity.

According to another variant embodiment, the optical element may be located on the exterior of said cavity.

A process for fabricating an encapsulating cover for an electronic device comprises the following steps: providing a cover body comprising a front wall containing a through-passage, and, around this through-passage, a mounting face that has a bearing surface, and, set back with respect to this surface, at least one local void, and providing an optical element that lets light pass and that has a mounting face; dispensing a drop of adhesive into said local void of the cover body; mounting the optical element above the cover body in a position such that the mounting face of the optical element bears against the bearing surface of the mounting face of the cover body and against the drop of adhesive, so that the drop of adhesive has a portion that is covered by the optical element and an uncovered portion beyond one edge of the optical element; at least partially curing the uncovered portion of the drop of adhesive by means of a first piece of equipment so as to locally fasten the optical element to the front wall of the cover; and completely curing the drop of adhesive by means of a second piece of equipment, so as to completely fasten the optical element to the front wall of the cover.

The bottom of said void of the cover body may comprise a protruding local bump that is located a distance away from said bearing surface and the drop of adhesive may be dispensed above said local bump, the covered portion and the uncovered portion of the drop of adhesive being located above the protruding bump.

Said drop of adhesive may be suitable for being cured under the effect of light radiation and heat and the first piece of equipment may be able to emit light radiation in the direction of the uncovered portion of the drop of adhesive, via said local void, and said second piece of equipment may be a baking oven.

Said optical element may be mounted on said cover body with a transferring and retaining tool that said first piece of equipment bears.

### BRIEF DESCRIPTION OF THE DRAWINGS

Encapsulating covers, methods for fabricating such encapsulating covers and electronic packages will now be described by way of non-limiting example, said covers, methods and packages being illustrated in the drawings, in which:

FIG. 1 shows a cross-sectional view of one portion of an encapsulating cover;

FIG. 2 shows a view of one side of the portion of encapsulating cover of FIG. 1;

FIG. 3 shows a cross section through an electronic package including a variant embodiment of the encapsulating cover of FIGS. 1 and 2;

FIG. 4 shows a cross section through another electronic package including another variant embodiment of the encapsulating cover of FIGS. 1 and 2; and

FIG. 5 shows a cross section through another electronic package including another variant embodiment of the encapsulating cover of FIGS. 1 and 2.

### DETAILED DESCRIPTION

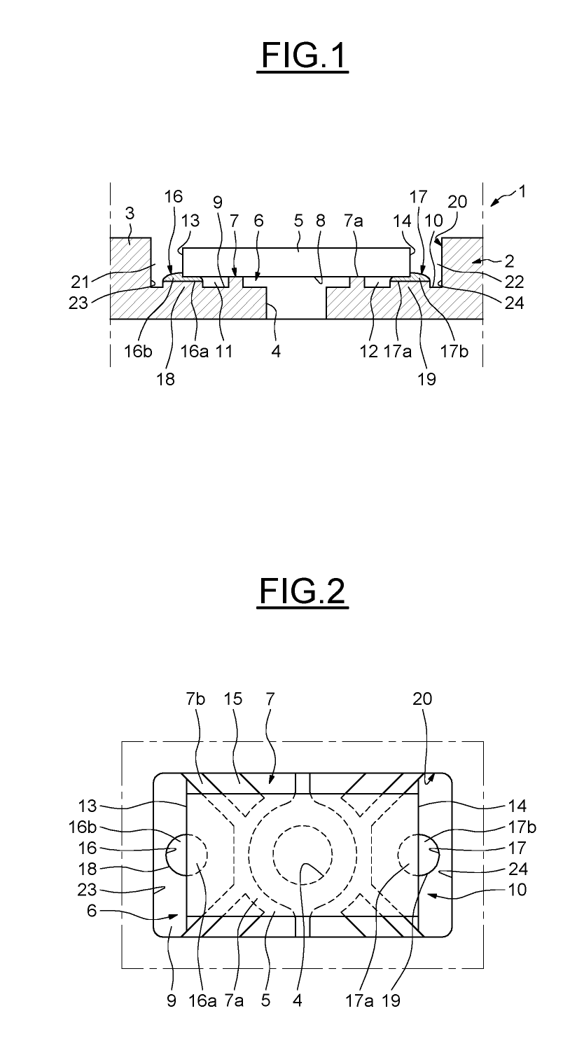

FIGS. 1 and 2 illustrate an encapsulating cover 1 for an electronic package which comprises a cover body 2 (partially shown) comprising a front wall 3 containing a through-passage 4, and which comprises an optical element 5 that lets light pass, the optical element 5 being placed facing the through-passage 4. The optical element, for example, takes the form of a rectangular plate.

The front wall 3 has, around the through-passage 4, a mounting face 6 that comprises a bearing surface 7 against which a mounting (rear) face 8 of the optical element 5 bears, the optical element 5 being arranged in a longitudinal direction, the central part of the optical element 5 covering the through-passage 4. The peripheral walls 23 and 24 along with mounting face 6 define a cavity in the front wall 3. The optical element 5 is received within the cavity. The through passage 4 extends from the mounting face at the back of the cavity through a rear portion of the front wall 3.

The mounting face 6 of the front wall 3 comprises, in regions that are longitudinally opposite with respect to the through-passage 4, local voids 9 and 10 that are set back or recessed with respect to the bearing surface 7, that create spaces 11 and 12 between the mounting face 8 of the optical element 5 and the bottoms of the voids 9 and 10 and that extend and are uncovered, i.e. not covered by the optical element 5, beyond opposite edges 13 and 14 of the optical element 5.

The bearing surface 7 has an annular zone 7a that extends all the way around the through-passage 4 and that passes between the through-passage 4 and the voids 9 and 10. Optionally, the mounting face 6 comprises complementary voids 15 that are set back or recessed with respect to the bearing surface 7, so that the bearing surface 7 contains a plurality of zones 7b that radiate from the annular zone 7a and that define the voids 9, 10 and 15.

The optical element 5 is fastened to the mounting face 6 by way of local drops of fastening adhesive 16 and 17 that extend locally into the voids 9 and 10 and that have portions 16a and 17a that are covered by end parts of the optical element 5, which parts are adjacent to the opposite edges 13 and 14 of the optical element 5, and uncovered portions 16b and 17b that are located beyond the opposite edges 13 and 14 of the optical element 5, respectively.

Advantageously, the bottoms of the voids 9 and 10 contain protruding bumps 18 and 19 that have end faces that lie facing and a distance away from the mounting face 8 of the optical element 5 and that extend beyond the opposite edges 13 and 14 of the optical element 5, so that the spaces 11 and 12 contain local portions that are located between the protruding bumps 18 and 19 and the face 8 of the optical element 5.

Advantageously, the drops of adhesive 16 and 17 are located on the protruding bumps 18 and 19. Nevertheless, the drops of adhesive 16 and 17 may extend beyond the edges of the protruding bumps 18 and 19, without however reaching the annular zone 7a of the bearing surface 7.

Advantageously, the front wall 3 contains a housing 20, for example of rectangular outline, the bottom of which forms the mounting face 6 that forms the bearing surface 7, the voids 9 and 10 and optionally the voids 15, so that the optical element 5 is freely, partially or completely engaged in the housing 20.

Spaces 21 and 22 are provided between the edges 13 and 14 of the optical element 5 and the opposite walls 23 and 24 of the housing 20, so that the portions 16b and 17b of the drops of adhesive 16 and 17 are uncovered and accessible.

The encapsulating cover 1 may be obtained in the following way.

A cover body 2, which is for example obtained by molding or machining an original plate, and an optical element 5, which is, for example, obtained by dicing an original plate, are provided separately. For example, the cover body 2 comprises an epoxy resin and the optical element 5 comprises a piece of glass the bulk of which has been treated and/or that is covered with a layer forming a light filter and/or a lens that, for example, diffracts or focuses light.

For example, using a syringe (not shown), drops of adhesive 16 and 17 are dispensed, in the liquid state, locally into the voids 9 and 10 of the mounting face 6 of the cover body 2. More specifically, the drops of adhesive 16 and 17 are dispensed onto the protruding bumps 18 and 19. By virtue of capillarity effects, the drops of adhesive 16 and 17 have a tendency to remain on the protruding bumps 18 and 19 and do not flow towards the rest of the voids 9 and 10. In particular, the drops of adhesive 16 and 17, in the liquid state, do not reach the bearing surface 7. The drops of adhesive are, for example, epoxy-based.

Using a transferring and positioning tool (not shown), for example one employing suction, the optical element 5 is mounted, in the desired position, so as to have surface 8 bear against the bearing surface 7 of the mounting face 6. The end parts of the optical element 5, which parts are adjacent to its edges 13 and 14, squash the drops of adhesive 16 and 17 to form their covered portions 16a and 17a and the uncovered portions 16b and 17b.

Immediately, while it is held, a step of retaining the optical element 5 locally on the cover body 2 is carried out by means of a first piece of equipment (not shown).

For example, the transferring and positioning tool being equipped with a piece of equipment suitable for emitting ultraviolet light radiation, this emission is temporally activated in the direction of the uncovered portions 16b and 17b of the drops of adhesive 16 and 17, via the spaces 21 and 22, so as to at least partially cure the drops of adhesive 16 and 17 and to achieve local retention of the optical element 5 on the cover body 2.

Subsequently, the transferring and positioning tool is removed.

In a subsequent step, the optical element 5 is definitively fastened to the cover body 2 by means of a second piece of equipment (not shown).

For example, the encapsulating cover 1 is transferred to a baking oven, so as to completely cure, at a suitable temperature, the drops of adhesive 16 and 17 and to completely fasten the optical element 5 to the cover body 2.

Of course, the adhesive chosen is able to be cured by ultraviolet radiation and thermally—it is for example a suitable epoxy adhesive.

As a result of the above, during the transportation of the encapsulating cover 1 between the mounting station and the station in which the optical element 5 is completely fastened to the cover body 2, or during any other handling operations between the mounting and definitive fastening, the optical element 5 preserves its position with respect to the cover body 2, by virtue of the local fastening achieved immediately after the optical element 5 is mounted on the cover body 2.

Examples of ways in which the encapsulating cover 1 may be used in the production of electronic packages will now be described.

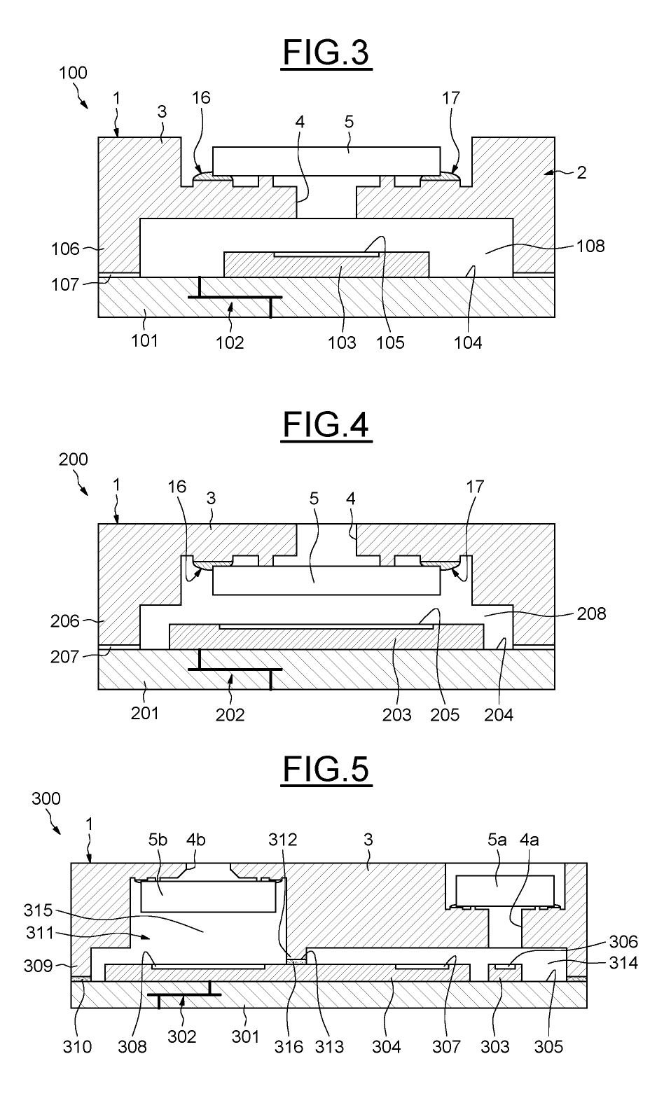

According to one example embodiment illustrated in FIG. 3, an electronic package 100 comprises a substrate or carrier 101 including an integrated network of electrical interconnects 102, connecting one face to the other, and an electronic chip 103 that is mounted on a front mounting face 104 of the carrier 101.

The chip 103 may be connected to the network of electrical interconnects 102 by electrically conductive wires or by balls that are interposed between a back face of the chip 103 and the front mounting face 104 of the carrier 101.

In its front face, the chip 103 comprises an integrated optical component 105 forming a sensor or a light emitter.

The front wall 3 of the encapsulating cover 1 is located in front of and a distance above the chip 103, the through-passage 4 and the optical element 5 being located facing the optical component 105 of the chip 103.

The cover body 2 furthermore comprises a peripheral wall 106 that protrudes backward with respect to the front wall 3, which is located at a distance from the periphery of the chip 103 and the back end of which is fastened to the mounting face 104 of the carrier 101 by a bead of adhesive 107, so that the encapsulating cover defines a cavity 108 in which the chip 103 is located.

The optical element 5 is located on the exterior of the cavity 108 on the front side of the front wall 3, so that light originating from the exterior reaches the cavity 108 by passing through the optical element 5 and then through the through-passage 4 in the front wall 3 of the cover body 2, and vice versa.

Advantageously, the optical element 5 of the encapsulating cover 1 is placed, with respect to the integrated optical component 105 of the chip 103, so that their optical axes are aligned.

According to one fabricating method, the optical element 5 is mounted on the front wall 3, as described above, then the encapsulating cover 1 is mounted on the carrier 101, the latter being equipped beforehand with the chip 103.

According to another embodiment, the encapsulating cover 1 is mounted on the carrier 101, the latter being equipped beforehand with the chip 103, then the optical element 5 is mounted on the front wall 3, as described above.

According to another example embodiment illustrated in FIG. 4, an electronic package 200 comprises a substrate or carrier 201 including an integrated network of electrical interconnects 202, connecting one face to the other, and an electronic chip 203 that is mounted on a front mounting face 204 of the carrier 201.

The chip 203 may be connected to the network of electrical interconnects 202 by electrically conductive wires or by balls that are interposed between a back face of the chip 203 and the front mounting face 204 of the carrier 201.

In its front face, the chip 203 comprises an integrated optical component 205 forming a sensor or a light emitter.

The front wall 3 of the encapsulating cover 1 is located in front of and a distance above the chip 203, the through-passage 4 and the optical element 5 being located facing the optical component 205 of the chip 203.

The cover body 2 furthermore comprises a peripheral wall 206 that protrudes backward with respect to the front wall 3, which is located at a distance from the periphery of the chip 203 and the back end of which is fastened to the mounting face 204 of the carrier 201 by a bead of adhesive 207, so that the encapsulating cover 1 defines a cavity 208 in which the chip 203 is located.

The optical element 5 is located on the interior of the cavity 208 on the back side of the front wall 3, so that light originating from the exterior reaches the cavity 208 by passing through the through-passage 4 in the front wall 3 of the cover body 2 and then through the optical element 5, and vice versa.

Advantageously, the optical element 5 of the encapsulating cover 1 is placed, with respect to the integrated optical component 205 of the chip 203, so that their optical axes are aligned.

According to one fabricating method, the optical element 5 is mounted on the front wall 3, as described above, then the encapsulating cover 1 is mounted on the carrier 201, the latter being equipped beforehand with the chip 203.

According to another example embodiment illustrated in FIG. 5, an electronic package 300 comprises a substrate or carrier 301 including an integrated network of electrical interconnects 302, connecting one face to the other, and electronic chips 303 and 304 that are mounted on a front mounting face 305 of the carrier 301 and that are spaced apart longitudinally.

The chips 303 and 304 may be connected to the network of electrical interconnects 302 by electrically conductive wires or by balls that are interposed between their back faces and the front mounting face 305 of the carrier 301.

The front face of the chip 303 comprises an integrated light emitter 306.

The front face of the chip 304 comprises two integrated light sensors 307 and 308 that are spaced apart longitudinally, the sensor 307 being beside the emitter 306.

The front wall 3 of the encapsulating cover 1 is located in front of and a distance above the chips 303 and 304.

The cover body 2 comprises a peripheral wall 309 that protrudes backward with respect to the front wall 3, which is located at a distance from the periphery of the chips 303 and 304 and the back end of which is fastened to the mounting face 305 of the carrier 301 by a bead of adhesive 310, so that the encapsulating cover 1 defines a cavity 311 in which the chips 303 and 304 are located.

The cover body 2 furthermore comprises a transverse interior partition 312 that protrudes backward with respect to the front wall 3, and that has a back indent 313 through which the chip 304 passes. The interior partition 312 lies a distance away from and extends between the sensors 307 and 308 of the chip 304 and divides the cavity 311 into two chambers 314 and 315, so that the emitter 306 and the sensor 307 are in the chamber 314 and the sensor is in the chamber 315.

A bead of adhesive 316 is interposed between the interior partition 312 and the chip 304 and, on either side of the chip 304, between the interior partition 312 and the carrier 301.

In this example embodiment, the front wall 3 of the cover body 2 has, this time, through-passages 4a and 4b that are located facing the emitter 306 of the chip 303 and facing the sensor 308 of the chip 304, respectively.

The front wall 3 of the cover body 2 is, this time, equipped with optical elements 5a and 5b that are equivalent to the optical element 5, that are associated with the through-passages 4a and 4b and that are mounted, on the front wall 3, in an equivalent way to the way described above with reference to FIGS. 1 and 2.

The optical element 5a is on the exterior of the chamber 314, in a way equivalent to the way described above with reference to FIG. 3.

The optical element 5b is on the interior of the chamber 315, in a way equivalent to the way described above with reference to FIG. 4.

According to one fabricating method, the optical elements 5a and 5b are mounted on the front wall 3, as described above, then the encapsulating cover 1 is mounted on the carrier 301, the latter being equipped beforehand with the chips 303 and 304.

According to another fabricating method, the optical element 5b is mounted on the front wall 3, as described above, then the encapsulating cover 1 is mounted on the carrier 301, the latter being equipped beforehand with the chips 303 and 304. Next, the optical element 5b is mounted on the front wall 5, as described above.

The electronic package 300 may operate in the following way.

The emitter 306 of the chip 303 emits light radiation, for example infrared radiation, towards the exterior through the optical element 5a. This light radiation, present in the chamber 314, is sensed by the sensor 307 of the chip 304. The sensor 308 of the chip 304 senses exterior light radiation through the optical element 5b. Processing of the signals generated by the sensors 307 and 308 may allow the package 300 to form a means for detecting the proximity of a body.

1. An encapsulating cover for an electronic package, comprising:
a cover body including a front wall containing a through-passage;
an optical element configured to let light pass through, said optical element being placed facing the through-passage and being fastened to said front wall by at least one drop of fastening adhesive;
wherein the front wall of the cover body has, around said through-passage, a mounting face that comprises:
a bearing surface against which a mounting face of the optical element bears;
at least one local void that is set back with respect to said bearing surface so as to provide a space between the mounting face of the optical element and the mounting face at the local void, wherein the at least one local void extends beyond an edge of the optical element, and wherein a bottom of the local void contains a protruding bump that lies facing and a distance away from the mounting face of the optical element and that extends beyond said edge of the optical element; and
wherein the drop of fastening adhesive extends locally into said local void and over the protruding bump, the drop of fastening adhesive having a first portion that is covered by the optical element and a second portion, located beyond said edge of the optical element, that is uncovered by the optical element.

2. The cover according to claim 1, wherein said local void is located a distance away from said through-passage.

3. The cover according to claim 1, wherein the bearing surface comprises a zone that extends all the way around said through-passage and that passes between said through-passage and said local void.

4. The cover according to claim 1, wherein said front wall contains a housing the bottom of which comprises said mounting face, a space being provided between said edge of the optical element and a side wall of the housing, the uncovered portion of the drop of fastening adhesive being located in this space.

5. An electronic package, comprising:
a carrier equipped, on a mounting face of the carrier, with at least one electronic chip including an optical component; and
an encapsulating cover comprising:
a cover body including a front wall containing a through-passage;
an optical element configured to let light pass through, said optical element being placed facing the through-passage and being fastened to said front wall by at least one drop of fastening adhesive;
wherein the front wall of the cover body has, around said through-passage, a mounting face that comprises:
a bearing surface against which a mounting face of the optical element bears;
at least one local void that is set back with respect to said bearing surface so as to provide a space between the mounting face of the optical element and the mounting face at the local void, wherein the at least one local void extends beyond an edge of the optical element, and wherein a bottom of the local void contains a protruding bump that lies facing and a distance away from the mounting face of the optical element and that extends beyond said edge of the optical element; and
wherein the drop of fastening adhesive extends locally into said local void and over the protruding bump, the drop of fastening adhesive having a first portion that is covered by the optical element and a second portion, located beyond said edge of the optical element, that is uncovered by the optical element;
wherein the front wall equipped with the optical element of the cover body lies above and a distance away from the chip, and wherein the cover body comprises a peripheral wall that protrudes with respect to the front wall, lying around and a distance away from the chip and fastened to the mounting face of the carrier, so as to define a cavity in which the chip is located.

6. The package according to claim 5, wherein the optical element is located in the interior of said cavity.

7. The package according to claim 5, wherein the optical element is located on the exterior of said cavity.

8. A process for fabricating an encapsulating cover for an electronic device, comprising the following steps:
providing a cover body comprising a front wall containing a through-passage and, around this through-passage, a mounting face that has a bearing surface and further including, set back with respect to the bearing surface, at least one local void;
dispensing a drop of adhesive into said local void of the cover body;
mounting an optical element above the cover body in a position such that a mounting face of the optical element bears against the bearing surface of the mounting face of the cover body and against the drop of adhesive, so that the drop of adhesive has a first portion that is covered by the optical element and a second portion, beyond one edge of the optical element, that is uncovered by the optical element;
at least partially curing the uncovered portion of the drop of adhesive using a first piece of equipment so as to locally fasten the optical element to the front wall of the cover; and
completely curing the drop of adhesive using a second piece of equipment so as to completely fasten the optical element to the front wall of the cover.

9. The method according to claim 8, wherein the bottom of said void of the cover body comprises a protruding local bump that is located a distance away from said bearing surface and dispensing comprises dispensing the drop of adhesive above said local bump, the covered portion and the uncovered portion of the drop of adhesive being located above the protruding bump.

10. The method according to claim 8, wherein said drop of adhesive is suitable for being cured under the effect of light radiation and heat and wherein at least partially curing using the first piece of equipment comprises emitting light radiation in the direction of the uncovered portion of the drop of adhesive, via said local void, and wherein completely curing the drop of adhesive comprises baking in an oven.

11. The method according to claim 8, wherein mounting the optical element comprises using a transferring and retaining to position the optical element on said cover body, and wherein the transferring and retaining tool includes said first piece of equipment.

12. An encapsulating cover for an electronic package, comprising:
a body having a front face and a rear face;
a cavity extending into the body from the front face, said cavity having a peripheral wall and a bottom surface;
a through passage extending into the body from the bottom surface to the rear face;
wherein the bottom surface of the cavity includes a bearing surface and a protruding adhesive surface, wherein the bearing surface, protruding adhesive surface and bottom surface are not coplanar;
an optical element positioned within the cavity and having a mounting surface which is in direct contact with the bearing surface and which is further adhesively secured to the protruding adhesive surface by a drop of adhesive positioned in a void between the mounting surface and the protruding adhesive surface, said drop of adhesive including a first portion that is covered by the optical element and a second portion, located beyond an outer peripheral edge of the optical element, that is uncovered by the optical element.

13. The encapsulating cover of claim 12, wherein there is no material interposed between the mounting surface and the bearing surface.
